(19) United States
(12) Patent Application Publication
(10) Pub. No.: US 2018/0252952 A1
(43) Pub. Date: Sep. 6, 2018

(54) THIN FILM TRANSISTOR ARRAY SUBSTRATES, MANUFACTURING METHODS THEREOF AND DISPLAY DEVICES

(71) Applicant: Shenzhen China Star Optoelectronics Technology Co., Ltd., Shenzhen, Guangdong (CN)

(72) Inventor: Jia LI, Shenzhen, Guangdong (CN)

(73) Assignee: Shenzhen China Star Optoelectronics Technology Co., Ltd., Shenzhen, Guangdong (CN)

(21) Appl. No.: 15/515,149

(22) PCT Filed: Mar. 12, 2017
(86) PCT No.: PCT/CN2017/077521

§ 371 Date: Mar. 29, 2017

(30) Foreign Application Priority Data
Mar. 6, 2017 (CN) 201710127535.9

(51) Int. Cl. G02F 1/1368; H01L 29/786; H01L 27/12

(52) U.S. Cl. CPC G02F 1/1368; H01L 29/7869; G02F 2201/123; H01L 27/1218; H01L 27/1225; H01L 29/78603

(57) ABSTRACT

The present disclosure relates to a thin film transistor (TFT) array substrate, including a TFT arranged on a glass substrate in a matrix, and each of the TFTs electrically connect to a pixel electrode. The TFT includes an active layer, and the pixel electrode and the active layer are configured within one structure layer. The active layer is formed by a first portion of semiconductor material, and the pixel electrode is formed by a conductor transformed from a second portion of the semiconductor material. The first portion of the semiconductor material and the second portion of the semiconductor material are integrally formed, and the semiconductor material is metal oxide semiconductor material. The present disclosure further relates to a manufacturing method of the array substrate and a display device including the array substrate.

### BACKGROUND OF THE INVENTION

### 1. Field of the Invention

The present disclosure relates to display field, more particular to a thin film transistor (TFT) array substrate, a manufacturing method thereof, and a display device including the TFT array substrate.

### 2. Discussion of the Related Art

Flat display devices have been widely adopted due to attributes such as thin, low power consuming, and no-radiation. The flat display devices mainly include liquid crystal displays (LCDs) and organic light emitting displays (OLEDs). TFTs are the main component of the flat display devices, which may be formed on the glass substrate or plastic substrate, and, usually, the TFT is configured to be a switch device and a driving device of LCDs or OLEDs.

In the display industry, as the display size become bigger and bigger, high-resolution has been demanded greatly, which results in higher requirements of charging and discharging process with respect to the active semiconductor devices. The metal oxide semiconductor material, such as indium gallium zinc oxide (IGZO), has high carrier mobility, which is about 20-30 times greater than the amorphous silicon. As such, the charging and discharging rate of the TFT with respect to the pixel electrode may be greatly improved. The metal oxide semiconductor material also has a high turn-on current and a low turn-off current, which may enhance the response speed of the pixels and may enhance refresh rate. Thus, the enhanced response time may greatly improve the pixel scanning rate, so as to realize ultra-high resolution.

The thin film array substrate is manufactured by a plurality of masking-related manufacturing processes via structure pattern. Each of the masking-related manufacturing processes may respectively include masking process, exposure process, developing process, etching process and peeling process, wherein the etching process includes dry etching and wet etching. Currently, the manufacturing process of the thin film array substrate, at least, includes the masking-related manufacturing process as below:

(1) forming a gate electrode in a glass substrate via a first masking-related manufacturing process.

(2) forming an active layer on a gate insulation layer via a second masking-related manufacturing process after the gate insulation layer is formed on the gate electrode.

(3) forming a source electrode and a drain electrode on the active layer via a third masking-related manufacturing process.

(4) forming a pixel electrode within an interlayer dielectric layer via a fourth masking-related manufacturing process after the interlayer dielectric layer is formed on the source electrode and the drain electrode.

(5) forming the pixel electrode on the interlayer dielectric layer via a fifth masking-related manufacturing process.

The number of the masking-related manufacturing processes may be adopted to evaluate the difficulties of the manufacturing process of the TFT array substrate. Therefore, reducing the number of the masking-related manufacturing processes may lower down the costs.

### SUMMARY

The present disclosure provides a TFT and a manufacturing method thereof. By improving the pixel structure of the array substrate, the number of the masking-related processes may be reduced. Compared with the conventional technique, the difficulties of the manufacturing process may be reduced and may the cost may be lowered down.

In one aspect, a thin film transistor (TFT) array substrate, including: a TFT arranged on a glass substrate in a matrix, and each of the TFTs electrically connecting to a pixel electrode, wherein the TFT includes an active layer, and the pixel electrode and the active layer are configured within one structure layer. The active layer is formed by a first portion of semiconductor material, and the pixel electrode is formed by a conductor transformed from a second portion of the semiconductor material, wherein the first portion of the semiconductor material and the second portion of the semiconductor material are integrally formed, and the semiconductor material is metal oxide semiconductor material.

The metal oxide semiconductor material is indium gallium zinc oxide (IGZO) or indium gallium zinc tin oxide (IGZTO).

A width of the pixel electrode and the active layer is in a range from 200 to 2000 Å.

The second portion of the semiconductor material is transformed into the conductor to form the pixel electrode by conducting an ultraviolet (UV) lighting process or an ion implantation process.

The TFT further includes a gate electrode, a source electrode, and a drain electrode, wherein the gate electrode is formed on the glass substrate, a gate insulation layer covers the gate electrode, and the active layer and the pixel electrode are configured on the gate insulation layer. The active layer is on a top of the gate electrode. The source electrode and the drain electrode are spaced apart from each other and are formed on the active layer, and the drain electrode electrically connects to the pixel electrode.

The source electrode and the drain electrode are made of Au, Cu, Ni, or Ag.

The array substrate further includes a passivation layer covering the TFT array substrate.

In another aspect, a manufacturing method of the TFT array substrate, including: forming a metal oxide semiconductor thin film on the glass substrate via a deposition process; dividing the metal oxide semiconductor thin film into the first portion of the semiconductor material and the second portion of the semiconductor material via the masking-related process and the first portion and the second portion of the semiconductor material being integrally formed; configuring the first portion of the semiconductor material to be the active layer, and transforming the second portion of the semiconductor material into the conductor to form the pixel electrode.

The method further includes: S1: providing the glass substrate, and forming a gate electrode thin film layer on the glass substrate via the deposition process; S2: forming the patterned gate electrode from the gate electrode thin film layer via a first masking-related manufacturing process; S3: forming the gate insulation layer, the metal oxide semiconductor thin film, a source electrode thin film layer, and a drain electrode thin film layer on the glass substrate in sequence; S4: etching the metal oxide semiconductor thin film, the source electrode thin film layer, and the drain electrode thin film layer via a second masking-related manufacturing process, and preserving portions of the metal oxide semiconductor thin film and a source/drain electrode thin film layer 300 corresponding to the active layer and the pixel electrode; S5: forming the active layer, the pixel electrode, the source electrode, and the drain electrode from the metal oxide semiconductor thin film, the source electrode thin film layer, and the drain electrode thin film layer via a third masking-related manufacturing process.

The step S5 further including: S51: forming a photoresist layer on the source/drain electrode thin film layer; S52: forming a first area, a second area, and a third area by exposing and developing the photoresist layer via a halftone mask or a gray tone mask, wherein photoresist of the first area being completely maintained, a portion of the photoresist of the second area being maintained, and the photoresist of the third area being completely removed; S53: etching the source/drain electrode thin film layer within the third area, exposing a portion of the metal oxide semiconductor thin film to form the first portion of the semiconductor material within the corresponding first area and the corresponding second area, and to form the second portion of the semiconductor material within the corresponding third area; S54: configuring the first portion of the semiconductor material to be the active layer, and transforming the second portion of the semiconductor material into the conductor to form the pixel electrode; S55: removing the photoresist within the second area via an ashing process; S56: etching the source/drain electrode thin film layer within the second area, and forming the source electrode and the drain electrode within the first area, wherein the source electrode and the drain electrode are spaced apart from each other; S57: peeling off the photoresist within the first area.

In another aspect, a display device includes the TFT array substrate.

The present disclosure relates to the TFT array substrate, wherein the pixel electrode and the active layer are configured within one structure layer. The active layer is formed by the first portion of semiconductor material, and the pixel electrode is formed by the conductor transformed from the second portion of the semiconductor material, so as to enhance the performance of electrical transmission in the pixel electrode. Further, due to the pixel electrode and the active layer are configured within one structure layer and are made of same structure material in the same masking-related manufacturing process, the number of the masking-related manufacturing processes may be reduced, such that the difficulties of the process may be reduced.

### BRIEF DESCRIPTION OF THE DRAWINGS

FIG. 1 is a schematic view of a TFT array substrate in accordance with one embodiment of the present disclosure.

FIGS. 2a to 2l are examples of structures obtained by each steps of a manufacturing method in accordance with one embodiment in the present disclosure.

FIG. 3 is a schematic view of a display device in accordance with one embodiment of the present disclosure.

### DETAILED DESCRIPTION OF THE EMBODIMENTS

Following embodiments of the invention will now be described in detail hereinafter with reference to the accompanying drawings. However, there are plenty of forms to implement the present disclosure, and the invention should not be construed as limitation to the embodiments.

In the following description, in order to avoid the known structure and/or function unnecessary detailed description of the concept of the invention result in confusion, well-known structures may be omitted and/or functions described in unnecessary detail.

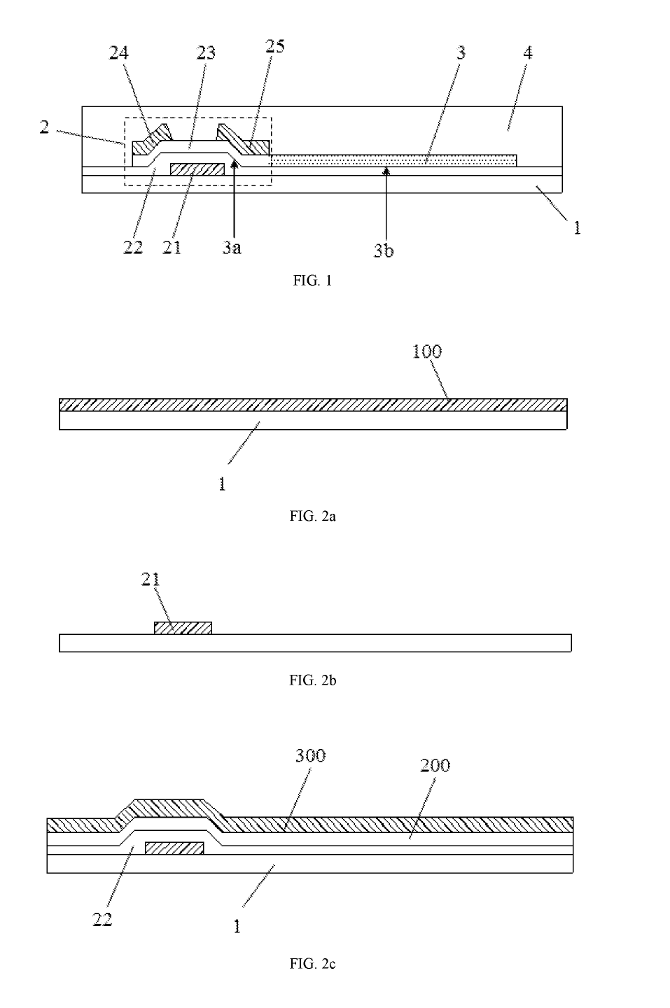

The present disclosure provides a TFT array substrate. As shown in FIG. 1, the TFT array substrate includes: a plurality of TFTs 2 (Only one of the TFTs is shown in the drawings) arranged on a glass substrate 1. The TFT 2 adopts an oxide semiconductor TFT technology. Each of the TFTs 2 electrically connecting to a pixel electrode 3.

Specifically, as shown in FIG. 1, the TFT 2 includes a gate electrode, a gate insulation layer 22, an active layer 23, a gate electrode, a source electrode 24, and a drain electrode 25. Wherein, the gate electrode 21 is formed on the glass substrate 1, and the gate insulation layer 2 covers the gate electrode 21. The active layer 23 is configured on the gate insulation layer 22 and is configured on a top of the gate electrode 21. The source electrode 24 and the drain electrode 25 are configured within one structure layer, wherein the source electrode 24 and the drain electrode 25 are spaced apart from each other, and are formed on the active layer 23. A channel area is formed within a gap configured between the source electrode 24 and the drain electrode 25, wherein the active layer 23 corresponds to the gap.

In one embodiment, as shown in FIG. 1, the pixel electrode 3 and the active layer 23 are configured within one structure layer. The active layer 23 is formed by a first portion of semiconductor material 3a, and the pixel electrode 3 is formed by a conductor transformed from a second portion of the semiconductor material 3b, wherein the first portion of the semiconductor material 3a and the second portion of the semiconductor material 3b are integrally formed, and the semiconductor material is metal oxide semiconductor material.

The drain electrode 25 further electrically connects to the pixel electrode 3. Further, as shown in FIG. 1, the array substrate further includes a passivation layer 4 covering the TFT array substrate 2.

The gate electrode 21 may adopt one or more of low resistance material, such as, but not limited to, Au, Cu, Ni, or Ag, and may be in a one layer structure or in a multilayer stacked structure.

The gate insulation layer 22 is mainly made of inorganic insulating material, such as SiNx, SiOx or a combination thereof. A width of the gate insulation layer 22 may be in a range from 2000 to 5000 Å.

The metal oxide semiconductor material, configured to form the pixel electrode 3 and the active layer 23, may adopt IGZO or IGZTO, and may be in a one layer structure or in a multilayer stacked structure. A width of the metal oxide semiconductor material may be in a range from 200 to 2000 Å. Wherein, the IGZO is consist of In, Ga, Zn, and O, and the IGZTO is consist of In, Ga, Zn, Sn, and O.

The second portion of the semiconductor material 3b is transformed into the conductor to form the pixel electrode 3 by conducting an ultraviolet (UV) lighting process or an ion implantation process.

As shown in FIG. 1, the pixel electrode 3 and the active layer 23 are configured within one structure layer, and the drain electrode 25 is configured on the active layer 23. Therefore, the drain electrode 25 may electrically connects the active layer 23 via (1) transforming the semiconductor material corresponding to a bottom of the drain electrode 25 into the conductor; (2) adopting a metal material with good diffusion properties to form the drain electrode 25, and transforming a portion of the semiconductor material under the drain electrode 25 into the conductor, wherein the metal material of the drain electrode 25 diffuses into the portion of semiconductor material. In one embodiment, the source electrode and the drain electrode adopt an active metal material which has trend to metal diffusion, such as, Au Cu Ni or Ag.

The passivation layer 4 is mainly made of inorganic insulating material, such as SiNx, SiOx or the combination thereof. A width of the passivation layer 4 may be in a range from 2000 to 4000 Å.

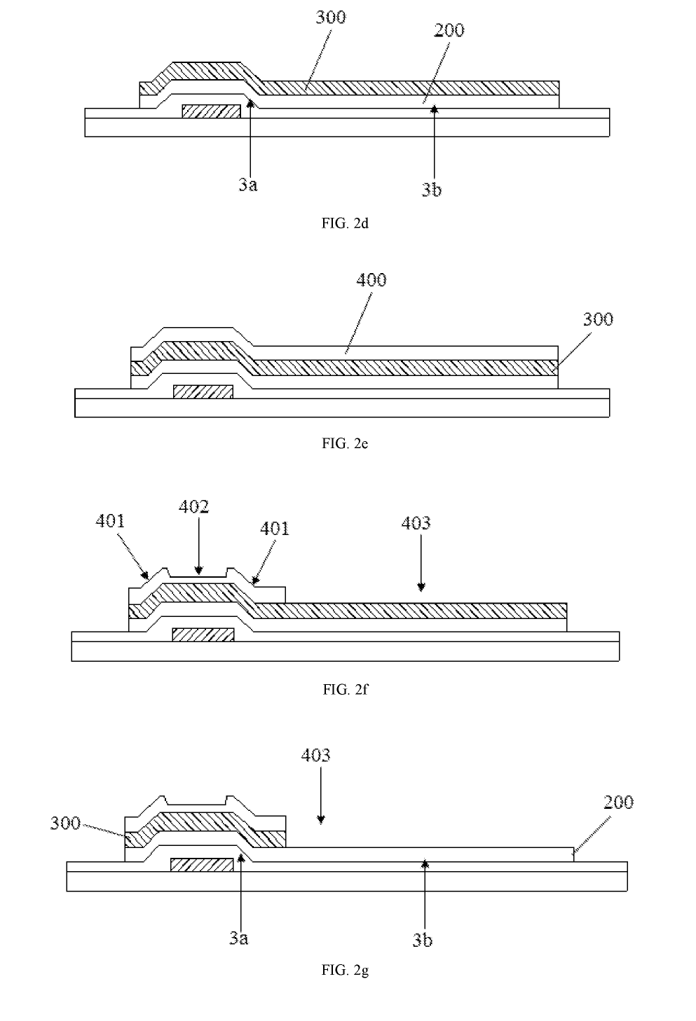

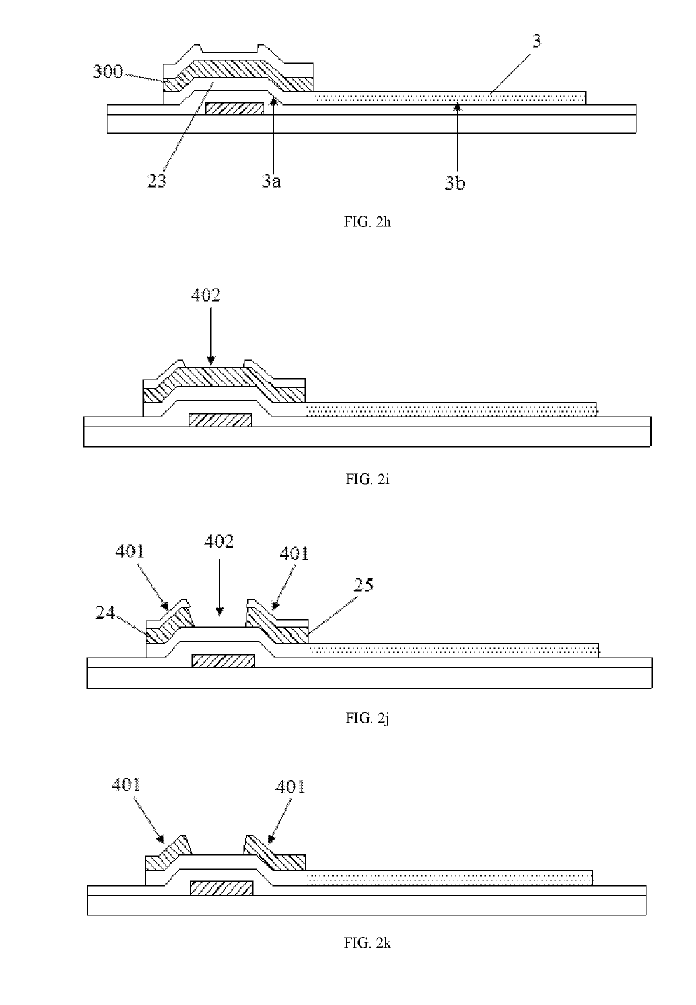

Referring to FIGS. 2a to 2k, a manufacturing method of the TFT array substrate, including: forming the gate electrode on the glass substrate via a first masking-related manufacturing process; etching the metal oxide semiconductor thin film including the first portion and the second portion of the semiconductor material via a second masking-related manufacturing process; forming the active layer, the pixel electrode, the source electrode, and the drain electrode via a third masking-related manufacturing process, wherein each of the masking-related manufacturing processes may respectively include masking process, exposure process, developing process, etching process and peeling process, wherein the etching process includes dry etch and wet etching. The masking-related manufacturing process has been a mature technique, thus, it may not be described here.

Specifically, referring to FIGS. 2a to 2l, the method mainly includes:

S1: as shown in FIG. 2a, providing the glass substrate 1, and forming a gate electrode material film layer 100 on the glass substrate 1. Wherein, the gate electrode material film layer 100 may be manufactured via a magnetron sputtering process, and the gate electrode material film layer 100 may be in a one layer structure or in a multilayer stacked structure.

S2: as shown in FIG. 2b, etching the gate electrode material film layer 100 to form the gate electrode 21 with a predetermined pattern via the first masking-related manufacturing process, wherein the gate electrode 21 is form by the gate electrode material film layer 100 via the dry etching process.

S3: as shown in FIG. 2c, forming the gate insulation layer 22, the metal oxide semiconductor thin film 200 and a source/drain electrode thin film layer 300 in sequence via a vapor deposit process. Wherein, the gate insulation layer 22 may be manufactured by a plasma enhancing chemical vapor deposition (PECVD) process, the metal oxide semiconductor thin film 200 may be manufactured by the magnetron sputtering process, the PECVD process, an atomic deposition (ALD) process, and a solution method, and the source/drain electrode thin film layer 300 may be manufactured by the magnetron sputtering process.

S4: as shown on FIG. 2d, etching the metal oxide semiconductor thin film 200 and the source/drain electrode thin film layer 300 via the second masking-related process, and preserving portions of the metal oxide semiconductor thin film and the source/drain electrode thin film layer corresponding to the active layer and the pixel electrode. Wherein, the portion of the metal oxide semiconductor thin film 200 corresponding to the active layer is the first portion of the semiconductor material 3a and the portion of the metal oxide semiconductor thin film 200 corresponding to the pixel electrode is the second portion of the semiconductor material 3b.

S5: forming the active layer, the pixel electrode, the source electrode, and the drain electrode from the metal oxide semiconductor thin film 200, the source/drain electrode thin film layer 300 via the third masking-related manufacturing process, and step S5 further including:

S51: as shown in FIG. 2e, forming a photoresist layer 400 on the source/drain electrode thin film layer 300.

S52: as shown in FIG. 2f, forming a first area 401, a second area 402, and a third area 403 by exposing and developing the photoresist layer 400 via a halftone mask or a gray tone mask, wherein photoresist of the first area 401 being completely maintained, a portion of the photoresist of the second area 402 being maintained, and the photoresist of the third area 403 being completely removed.

S53: as shown in FIG. 2g, etching the source/drain electrode thin film layer 200 within the third area 403, and a exposing portion of the metal oxide semiconductor thin film 200 within the corresponding first area 401 and the corresponding second area 402 is the first portion of the semiconductor material 3a, that is, the exposing portion of the metal oxide semiconductor thin film 200 within the corresponding third area 403 is the second portion of the semiconductor material 3b.

S54: as shown in FIG. 2h, configuring the first portion of the semiconductor material 3a to be the active layer 23, and transforming the second portion of the semiconductor material 3b into the conductor to form the pixel electrode 3. Specifically, transforming the second portion of the semiconductor material 3b into the conductor to form the pixel electrode 3 by conducting the UV lighting process or the ion implantation process via configuring the source/drain electrode thin film layer 300 within the first area and the second area to be as a mask plate.

S55: as shown in FIG. 2i, removing the photoresist within the second area 402 via an ashing process.

S56: as shown in FIG. 2j, etching the source/drain electrode thin film layer 300 within the second area 402, and forming the source electrode 24 and the drain electrode 25 within the first area 401, wherein the source electrode 24 and the drain electrode 25 are spaced apart from each other.

S57: as shown in FIG. 2k, peeling off the photoresist within the first area 401.

S6: as shown in FIG. 2l, forming the passivation layer 4 on the glass substrate 1 via the deposit process. Wherein, the passivation layer 4 may be manufactured by the PECVD process, and the passivation layer 4 covers the TFT 2 and the pixel electrode 3.

The present disclosure relates the TFT array substrate and the manufacturing method thereof, wherein the pixel electrode and the active layer are configured within one structure layer, and the active layer is formed by the first portion of semiconductor material, and the pixel electrode is formed by the conductor transformed from the second portion of the semiconductor material, so as to enhance the performance of electrical transmission in the pixel electrode. Further, due to the pixel electrode and the active layer are configured within one structure layer and are made of a same structure material in the same masking-related manufacturing process, the number of the masking-related manufacturing processes may be deduced, such that the difficulties of the process may be reduced, so as to lower down the costs.

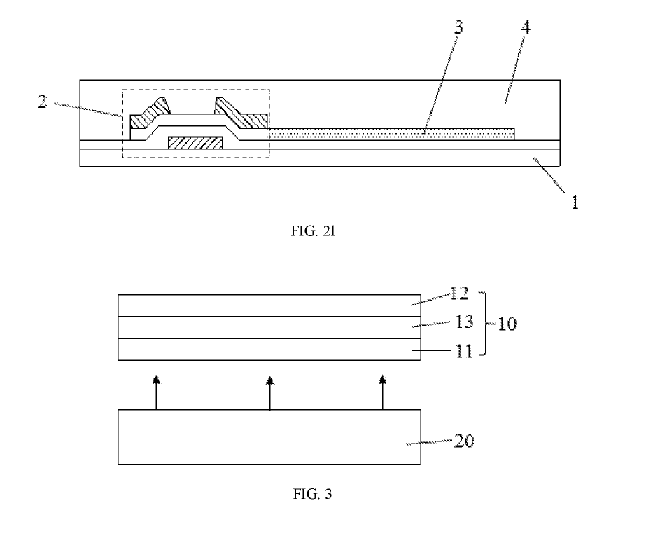

The present disclosure further relates to a display device, wherein the display device adopts the TFT array substrate in accordance with one embodiment in the present disclosure. The display device may be TFT-LCDs or OLEDs. Adopting the TFT array substrate provided in the present disclosure may enhance the performance and may lower down the costs. Specifically, consider the TFT-LCD as an example, referring to FIG. 3, the TFT-LCD includes a liquid crystal plate 10 and a backlight module 20, wherein the liquid crystal plate 10 is opposite to the backlight module 20. The backlight module 20 provides a displaying light source to the liquid crystal plate 10, such that, the liquid crystal plate 10 is capable of displaying images. The liquid crystal plate 10 further includes an array substrate 11, a filter substrate 12, and a liquid crystal layer 13 arranged between the array substrate 11 and the filter substrate 12, wherein the array substrate 11 is arranged opposite to the filter substrate 12. The array substrate 11 adopts the TFT array substrate in accordance with one embodiment of the present disclosure.

It should be noted that the relational terms herein, such as “first” and “second”, are used only for differentiating one entity or operation, from another entity or operation, which, however do not necessarily require or imply that there should be any real relationship or sequence. Moreover, the terms “comprise”, “include” or any other variations thereof are meant to cover non-exclusive including, so that the process, method, article or device comprising a series of elements do not only comprise those elements, but also comprise other elements that are not explicitly listed or also comprise the inherent elements of the process, method, article or device. In the case that there are no more restrictions, an element qualified by the statement “comprises a . . . ” does not exclude the presence of additional identical elements in the process, method, article or device that comprises the said element.

It is believed that the present disclosure is fully described by the embodiments, however, certain improvements and modifications may be made by those skilled in the art without departing from the principles of the present application, and such improvements and modifications shall be regarded as the scope of the present application.

What is claimed is:

1. A thin film transistor (TFT) array substrate, comprising:
a TFT arranged on a glass substrate in a matrix, and each of the TFTs electrically connecting to a pixel electrode, wherein the TFT comprises an active layer, and the pixel electrode and the active layer are configured within one structure layer;
the active layer is formed by a first portion of semiconductor material, and the pixel electrode is formed by a conductor transformed from a second portion of the semiconductor material, wherein the first portion of the semiconductor material and the second portion of the semiconductor material are integrally formed, and the semiconductor material is metal oxide semiconductor material.

2. The TFT array substrate according to claim 1, wherein the metal oxide semiconductor material is indium gallium zinc oxide (IGZO) or indium gallium zinc tin oxide (IGZTO).

3. The TFT array substrate according to claim 1, wherein a width of the pixel electrode and the active layer is in a range from 200 to 2000 Å.

4. The TFT array substrate according to claim 1, wherein the second portion of the semiconductor material is transformed into the conductor to form the pixel electrode by conducting an ultraviolet (UV) lighting process or an ion implantation process.

5. The TFT array substrate according to claim 1, wherein the TFT further comprises a gate electrode, a source electrode, and a drain electrode, wherein the gate electrode is formed on the glass substrate, a gate insulation layer covers the gate electrode, the active layer and the pixel electrode are configured on the gate insulation layer; the active layer is on a top of the gate electrode; the source electrode and the drain electrode are spaced apart from each other and are formed on the active layer, and the drain electrode electrically connects to the pixel electrode.

6. The TFT array substrate according to claim 5, wherein the source electrode and the drain electrode are made of Au, Cu, Ni, or Ag.

7. The TFT array substrate according to claim 5, wherein the array substrate further comprises a passivation layer covering the TFT array substrate.

8. A manufacturing method of TFT array substrates, comprising:
forming a metal oxide semiconductor thin film on a glass substrate via a deposition process;
dividing the metal oxide semiconductor thin film into a first portion of the semiconductor material and a second portion of the semiconductor material via a masking-related process and the first portion and the second portion of the semiconductor material being integrally formed;
configuring the first portion of the semiconductor material to be an active layer, and transforming the second portion of the semiconductor material into a conductor to form a pixel electrode.

9. The manufacturing method of TFT array substrates according to claim 8, wherein the method further comprises:
S1: providing the glass substrate, and forming a gate electrode thin film layer on the glass substrate via the deposition process;
S2: forming a patterned gate electrode from the gate electrode thin film layer via a first masking-related manufacturing process;
S3: forming a gate insulation layer, a metal oxide semiconductor thin film, a source/drain electrode thin film layer on the glass substrate in sequence;
S4: etching the metal oxide semiconductor thin film and the source/drain electrode thin film layer via a second masking-related manufacturing process, and preserving portions of the metal oxide semiconductor thin film, the source/drain electrode thin film layer corresponding to the active layer and the pixel electrode;
S5: forming the active layer, the pixel electrode, a source electrode, and a drain electrode from the metal oxide semiconductor thin film, the source/drain electrode thin film layer via a third masking-related manufacturing process, and the step S5 further comprising:
S51: forming a photoresist layer on the source/drain electrode thin film layer;
S52: forming a first area, a second area, and a third area by exposing and developing the photoresist layer via a halftone mask or a gray tone mask, wherein photoresist of the first area being completely maintained, a portion of the photoresist of the second area being maintained, and the photoresist of the third area being completely removed;
S53: etching the source/drain electrode thin film layer within the third area, exposing a portion of the metal oxide semiconductor thin film to form the first portion of the semiconductor material within the corresponding first area and the corresponding second area, and to form the second portion of the semiconductor material within the corresponding third area;
S54: configuring the first portion of the semiconductor material to be the active layer, and transforming the second portion of the semiconductor material into the conductor to form the pixel electrode;
S55: removing the photoresist within the second area via an ashing process;
S56: etching the source/drain electrode thin film layer within the second area, and forming the source electrode and the drain electrode within the first area, wherein the source electrode and the drain electrode are spaced apart from each other;
S57: peeling off the photoresist within the first area.

10. The manufacturing method of TFT array substrates according to claim 9, wherein the metal oxide semiconductor material is indium gallium zinc oxide (IGZO) or indium gallium zinc tin oxide (IGZTO).

11. The manufacturing method of TFT array substrates according to claim 9, wherein a width of the pixel electrode and the active layer is in a range from 200 to 2000 Å.

12. The manufacturing method of TFT array substrates according to claim 9, wherein the second portion of the semiconductor material is transformed into the conductor to form the pixel electrode by conducting an ultraviolet (UV) lighting process or an ion implantation process.

13. The manufacturing method of TFT array substrates according to claim 9, wherein the source electrode and the drain electrode are made of Au, Cu, Ni, or Ag.

14. A display device, comprising:
a TFT array substrate, wherein the TFT array substrate comprises:
a TFT arranged on a glass substrate in a matrix, and each of the TFTs electrically connecting to a pixel electrode, wherein the TFT comprises an active layer, and the pixel electrode and the active layer are configured within one structure layer;
the active layer is formed by a first portion of the semiconductor material, and the pixel electrode is formed by a conductor transformed from a second portion of the semiconductor material, wherein the first portion of the semiconductor material and the second portion of the semiconductor material are integrally formed, and the semiconductor material is metal oxide semiconductor material.

15. The display device according to claim 14, wherein the metal oxide semiconductor material is indium gallium zinc oxide (IGZO) or indium gallium zinc tin oxide (IGZTO).

16. The display device according to claim 14, wherein a width of the pixel electrode and the active layer is in a range from 200 to 2000 Å.

17. The display device according to claim 14, wherein the second portion of the semiconductor material is transformed into the conductor to form the pixel electrode by conducting an ultraviolet (UV) lighting process or an ion implantation process.

18. The display device according to claim 14, wherein the TFT further comprises a gate electrode, a source electrode, and a drain electrode, wherein the gate electrode is formed on the glass substrate, a gate insulation layer covers the gate electrode, the active layer and the pixel electrode are configured on the gate insulation layer; the active layer is on a top of the gate electrode; the source electrode and the drain electrode are spaced apart from each other and are formed on the active layer, and the drain electrode electrically connects to the pixel electrode.

19. The display device according to claim 18, wherein the source electrode and the drain electrode are made of Au, Cu, Ni, or Ag.

20. The display device according to claim 18, wherein the array substrate further comprises a passivation layer covering the TFT array substrate.
